(19) United States
(12) Patent Application Publication
(10) Pub. No.: US 2009/0116208 A1
(43) Pub. Date: May 7, 2009

(54) Electronic device electrical shielding

(75) Inventors: Aki Hekkala, Lumijoki (FI); Sami Ihme, Oulu (FI); Kari Hiltunen, Espoo (FI)

Correspondence Address: HARRINGTON & SMITH, PC, 4 RESEARCH DRIVE, Suite 202, SHELTON, CT, 06484-6212, US

(73) Assignee: Nokia Corporation

(21) Appl. No.: 11/982,665

(22) Filed: Nov. 2, 2007

(51) Int. Cl. H05K 9/00

(52) U.S. Cl. 361/816

(57) ABSTRACT

Disclosed herein is a shield for electrically shielding an electronic device. The shield includes a molded base and a first coating layer. The molded base includes a first portion and a second portion. The second portion comprises a resilient material connected to the first portion by being molded or extruded onto the first portion. The first coating layer is deposited on the second portion. The first coating layer includes an electrically conductive material.

### BACKGROUND OF THE INVENTION

1. Field of the Invention

The invention relates to electrical shielding and, more particularly, to electrical shielding of electronic components within an electronic device.

2. Brief Description of Prior Developments

Electromagnetic interference (EMI) shielding of electronical components of different kinds of devices has been traditionally done by using separate shields. For mobile devices this has not always been a good solution because it requires additional space. A problem in the shielding field is that either there is not enough shielding performance or the solutions used for the necessary performance has many other undesirable properties. U.S. Pat. No. 5,566,055 discloses a conventional shielded enclosure for electronic devices.

As consumers demand increased functionality from electronic devices, there is a need to provide improved devices having increased capabilities (and thus increased component capacity and/or size) while maintaining robust and reliable product configurations. Additionally, due to the demand for miniaturized devices, the increased capabilities should be provided in a compact yet user-friendly design.

Accordingly, there is a desire to provide an improved electrical shielding configuration for electronic devices.

### SUMMARY OF THE INVENTION

In accordance with one aspect of the invention, a shield for electrically shielding an electronic device is disclosed. The shield includes a molded base and a first coating layer. The molded base includes a first portion and a second portion. The second portion comprises a resilient material connected to the first portion by being molded or extruded onto the first portion. The first coating layer is deposited on the second portion. The first coating layer includes an electrically conductive material.

In accordance with another aspect of the invention, a cover for an electronic device is disclosed. The cover includes a first molded portion, a first material layer, a second portion, and a second material layer. The first material layer is on the first molded portion. The first material layer includes a first electrically conductive material. The second portion is between the first molded portion and the first material layer. The second portion is connected to the first molded portion by being integrally formed on the first molded portion. The second material layer is on the first material layer. The second material layer includes a second different electrically conductive material.

In accordance with yet another aspect of the invention, a method of forming an electrical shield for an electronic device is disclosed. A first base portion is molded. A second base portion is molded or extruded integrally on the first base portion. The second base portion includes a resilient material. A first coating layer is deposited on the first and second base portions. The first coating layer includes a first electrically conductive material.

### BRIEF DESCRIPTION OF THE DRAWINGS

The foregoing aspects and other features of the invention are explained in the following description, taken in connection with the accompanying drawings, wherein:

FIG. 1 is a perspective view of a portable electronic device comprising features of the invention;

FIG. 2 is a cross section view taken at line 2-2 of the device shown in FIG. 1;

FIG. 3 an exemplary method of forming an electrical shield for the electronic device shown in FIG. 1;

FIG. 4 is a cross section view of the electrical shield after forming a first base portion;

FIG. 5 is a cross section view of the electrical shield after forming a second base portion;

FIG. 6 is a cross section view of the electrical shield after depositing a first coating layer; and

FIG. 7 is a cross section view of the electrical shield after depositing a second coating layer.

### DETAILED DESCRIPTION OF THE PREFERRED EMBODIMENT

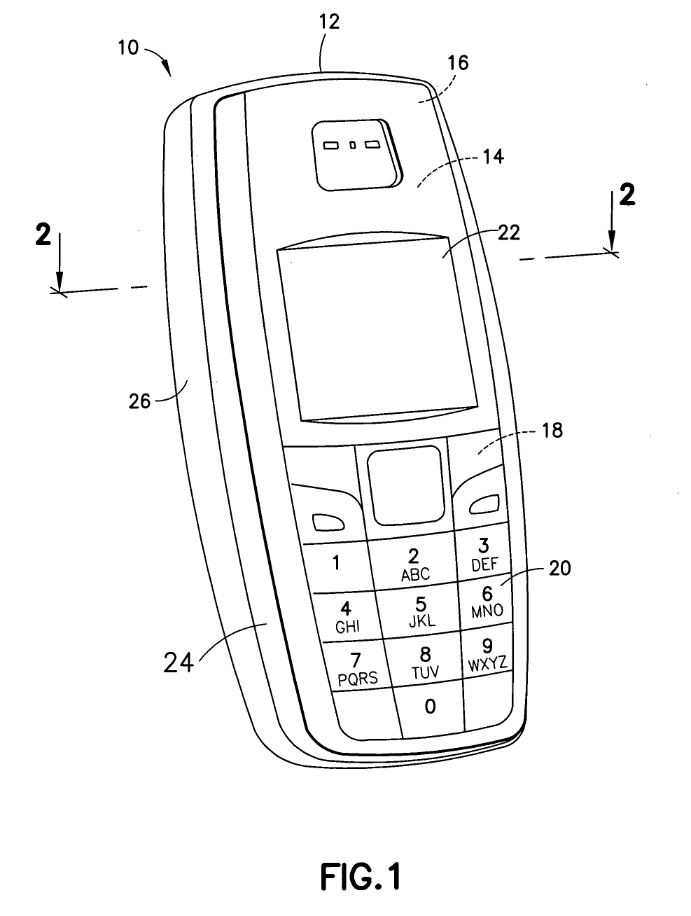

Referring to FIG. 1, there is shown a perspective view of a portable electronic device 10 incorporating features of the invention. Although the invention will be described with reference to the exemplary embodiment shown in the drawings, it should be understood that the invention can be embodied in many alternate forms of embodiments. In addition, any suitable size, shape or type of elements or materials could be used.

In this embodiment the device 10 comprises a mobile telephone. However, in alternate embodiments the device could comprise any suitable type of electronic device adapted to removably receive an electronic module, such as a memory card. For example, the device 10 could comprise a digital camera, a music player, a hand-held gaming device, a PDA, or a notebook computer. The telephone 10 generally comprises a housing 12, a transceiver 14 connected to an antenna 16, a controller 18, a keypad 20 and a display 22. The housing 12 includes a first housing section 24 and a second housing section 26. In alternate embodiments, more than two housing sections could be provided. Additionally, the telephone 10 can have any suitable type of features as known in the art.

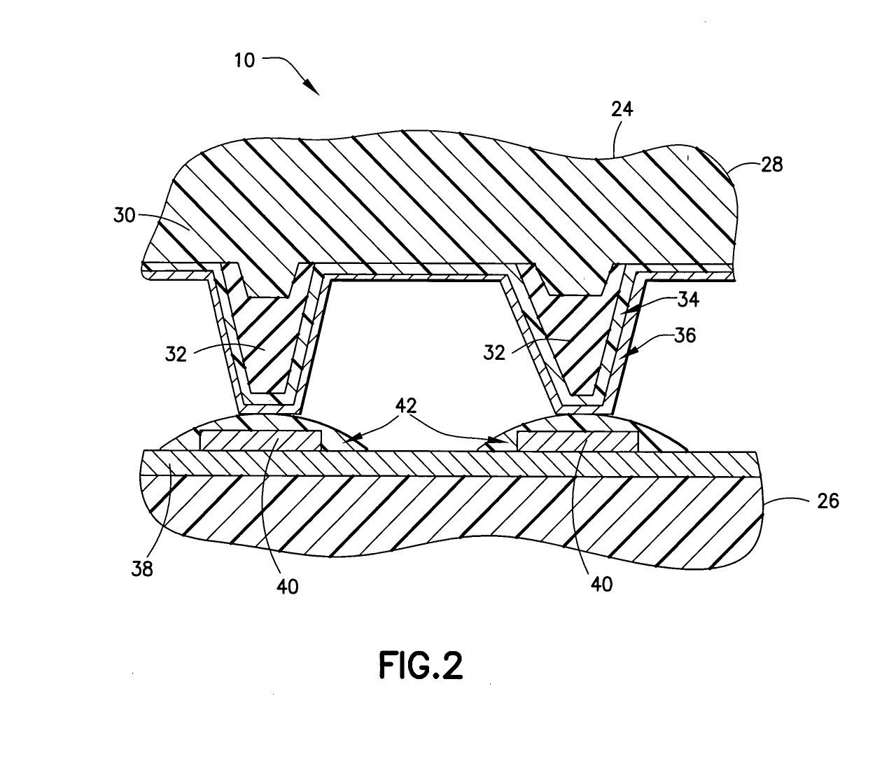

FIG. 2 illustrates a partial cross-section view of electronic device 10. The first housing section, or cover, 24 comprises a base portion 28 having a substantially rigid portion 30 and a substantially resilient portion 32, and conductive coating layers 34, 36. The substantially rigid portion 30 may be a non-conductive polymer material, such as plastic for example. It should be noted that in alternate embodiments, the substantially rigid portion 30 may comprise an electrically conductive metallic material, or any suitable thermally conductive material. The substantially resilient portion 32 may be an electrically non-conductive elastomer material for example. However, alternate embodiments may comprise any suitable materials.

The second housing section 26 comprises a printed circuit board (PCB), or printed wiring board (PWB), 38, comprising traces (which may be copper or any other electrically conductive material based traces) 40, and a surface finish 42 over portions of the copper traces 40. Portions of the first housing section 24 may contact portions of the second housing section 26 as shown in FIG. 2. The resilient portion 32 works as a spring to provide electrical contact between the housing portions 36, 42. The resilient portion 32 (including all fixing methods) creates the pressure necessary to form a suitable electrical connection.

The base portion 28 comprises non-conductive materials which serve as a mechanical base for the cover 24. However, it should be noted that the base portion 28 may comprise an electrically conductive material. For example, the conductive material may be a poorly conductive material (such as Mg after passivation) wherein, without the coating layer(s), an inadequate electrical connection is achieved. This conductive material may then provide other advantages such as rigidity or thermal conductivity. From a manufacturability point of view, the base portion 28 is formed as a 2-component (2K) or 2-shot molding technique (plastic part 30+elastomer 32 in the same manufacturing process). In alternate embodiments, the base portion 28 may be formed by molding or any other suitable manufacturing process (such as extrusion for example) wherein the resilient portion 32 may be added to, or integrally formed with, the rigid portion 30. It should be noted that the 2K or 2-shot molding technique may not require an additional post extrusion step. However, any suitable molding process steps may be included (even though some manufacturing advantages may be lost). After the molding process of the base portion 28 (comprising the rigid portion 30 integral with the resilient portion 32), the base portion 28 is coated by conductive layers 34, 36. The conductive layers may be applied separately wherein the conductive layer 34 is a shield layer, and the conductive layer 36 is an environmental protection layer. This forms a continuous shield (cover 24) where there are less connection discontinuities compared to the prior art solutions. Furthermore, the contact impedance in the disclosed cover 24 is smaller (or lower) because the surface conductivities in the mating surfaces are high due to the conductive coatings 34, 36.

The conductive coating layer (or shield layer) 34 may be an electrically conductive layer such as copper (Cu) for example. However, alternate embodiments may comprise any other highly (electrically) conductive material. The conductive coating layer (or environmental protection layer) 36 may be an electrically conductive layer such as stainless steel (SuS) for example. However, alternate embodiments may comprise any other environmentally stable (in the electrical sense) and highly (electrically) conductive material.

It should also be noted that although the figures illustrate two conductive coatings 34, 36, any suitable number of coatings may be provided. For example, in one alternate embodiment, multiple layers of different materials may be provided. For example, in another alternate embodiment, a single coating layer may be applied, wherein the single coating layer is electrically stable (having a low contact impedance) in regards to environmental stresses.

As shown in FIG. 2, the conductive coating layer 34 may be deposited on rigid portion 30 and the resilient portion 32. This allows the resilient portion 32 to be surrounded by the rigid portion 30 on one end, and by the conductive coating 34 elsewhere. However, it should be noted that alternate boundaries for the resilient material 32 may be provided.

The portions of the cover, or shield, 24 may comprise any parts that are used to form a closed volume around the device 10 or parts of the device 10. However, in electronic devices, one of the volume boundaries may be the printed circuit board (PCB) where the techniques described above are not applied (i.e. the PCB is applied as such). Other parts or components may be coated with conductive layers, such that during the 2K molding process, the elastomer is applied where necessary. Subsequently, the coating layer(s) is applied to the molded parts (such as single modules, which may be a camera shielding for example).

The disclosed shield 24 provides a new way to achieve shielding without any extra components. The cover 24 of the device 10 is shaped during molding phase so that it has separate compartments or divides for different components. The cover 24 is then coated with conductive material which works as a shield. The cover 24 provides a continuous conductive coating (i.e. it is provided over connection areas of the cover 24 as shown in FIG. 2).

Conventional configurations use shaped cover parts which are combined with an elastomer shielding material in molding process. The conventional solutions use a conductive elastomer to connect the separate parts of the shielding structure together to form “as closed as possible” volumes. The different parts can be made of either from metal or some other very high conducting material or made from parts coated by conductive layers. One difference in the disclosed shield 24 over the conventional configurations is that the conductive layer 34, 36 is deposited on top of the molded cover (or base portion) 28 after the molding process.

The disclosed cover 24 provides mechanical shielding using a non-conductive elastomer with conductive coating(s). It should be noted that in alternate embodiments, the non-conductive elastomer may be a thermoplastic elastomer for example. The shielding provided by the disclosed cover 24 is more compact and easier to manufacture (as it does not require separate components) when compared to conventional configurations. For example, an assembly line may be simplified by providing less parts to assemble (i.e. integration level is increased). Additionally, the disclosed cover 24 provides many other advantages over conventional configurations including: improved electrical performance, wider range of elastomers available for the cover, improved mechanical properties, reduced total device thickness due to the compact shielding structures, improved aging properties, increased integration levels, increased production outputs, ease of care, and competitive cost.

It should be noted that although the figures illustrate electrical shielding within a portable electronic device, the disclosed shield may be applicable to any electrical devices where any additional electrical shielding is needed.

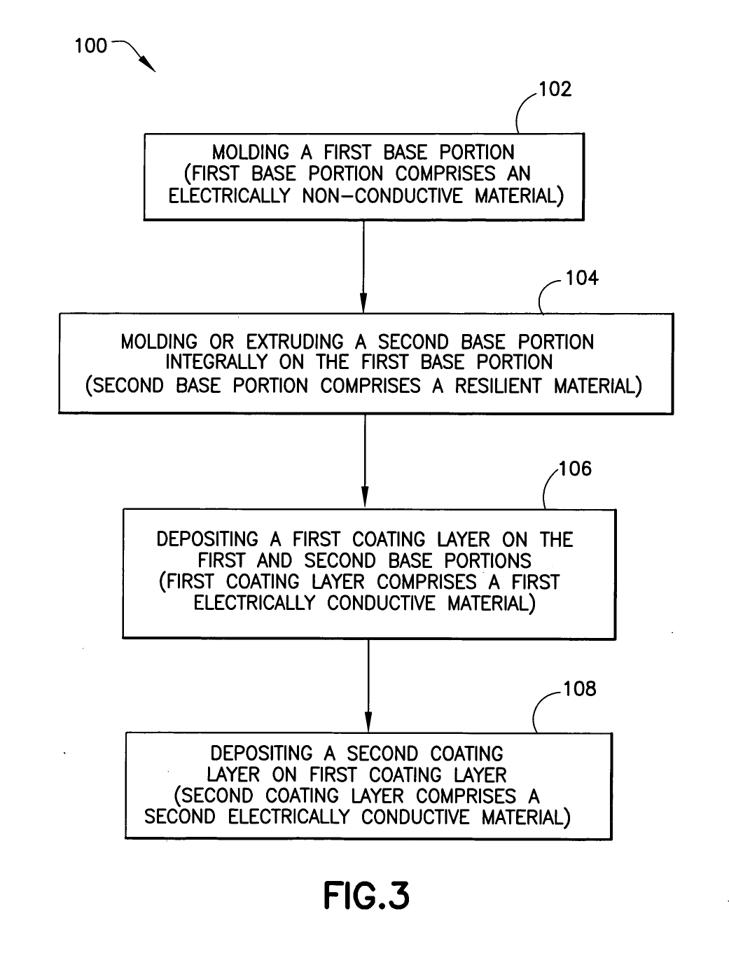

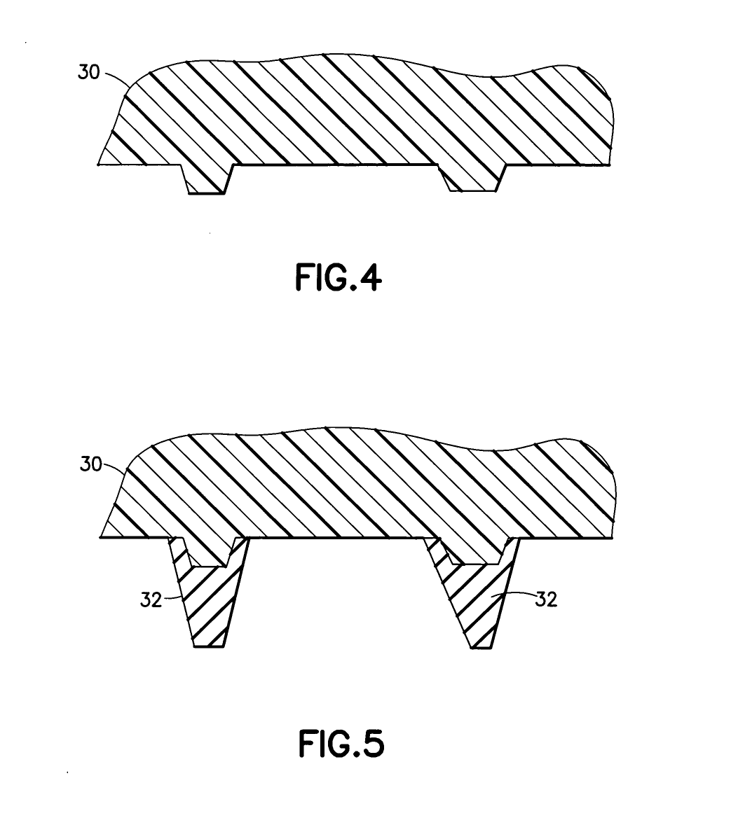

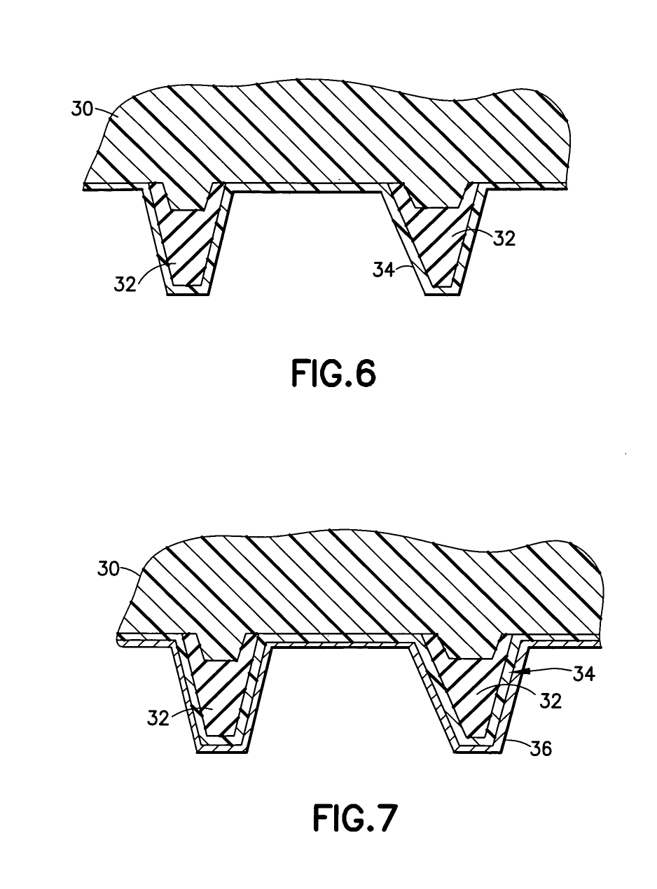

FIG. 3 illustrates an exemplary method 100 of forming an electrical shield for the electronic device 10. The method includes the following steps. Molding a first base portion 30 (step 102), wherein the first base portion 30 comprises an electrically non-conductive material. The molded first base portion (or rigid portion) 30 is illustrated in FIG. 4. Molding or extruding a second base portion 32 integrally on the first base portion 30 (step 104), wherein the second base portion 32 comprises a resilient material. The integrally molded second base portion (or resilient portion) 32 is illustrated in FIG. 5. The molding of the second base portion 32 may further comprise molding an elastomer base portion integrally with a polymer base portion. Depositing a first coating layer 34 on the first and second base portions 30, 32 (step 106), wherein the first coating layer 34 comprises a first electrically conductive material. FIG. 6 illustrates the first coating layer 34 deposited on the first and second base portions 30, 32. Depositing a second coating layer 36 on the first coating layer 34 (step 108), wherein the second coating layer 36 comprises a second electrically conductive material. FIG. 7 illustrates the second coating layer 36 deposited on the first coating layer 34.

It should be understood that the foregoing description is only illustrative of the invention. Various alternatives and modifications can be devised by those skilled in the art without departing from the invention. Accordingly, the invention is intended to embrace all such alternatives, modifications and variances which fall within the scope of the appended claims.

What is claimed is:

1. A shield for electrically shielding an electronic device comprising:
a molded base comprising a first portion and a second portion, wherein the second portion comprises a resilient material connected to the first portion by being molded or extruded onto the first portion; and
a first coating layer deposited on the second portion, wherein the first coating layer comprises an electrically conductive material.

2. The shield of claim 1 wherein the resilient material comprises an elastomer material.

3. The shield of claim 1 wherein the first coating layer comprises an electrically conductive material.

4. The shield of claim 1 wherein the first coating layer comprises copper.

5. The shield of claim 1 further comprising a second coating layer deposited on the first coating layer.

6. The shield of claim 5 wherein the second coating layer comprises an environmentally stable electrically conductive metal material.

7. The shield of claim 5 wherein the second coating layer comprises stainless steel.

8. The shield of claim 5 wherein the first coating layer is an electrical shield layer, and wherein the second coating layer is an environmental protection layer.

9. The shield of claim 1 wherein the first coating layer is deposited on the first portion and the second portion.

10. The shield of claim 1 wherein the first portion comprises an electrically non-conductive material.

11. A cover for an electronic device comprising:
a first molded portion;
a first material layer on the first molded portion, wherein the first material layer comprises a first electrically conductive material;
a second portion between the first molded portion and the first material layer, wherein the second portion is connected to the first molded portion by being integrally formed on the first molded portion; and
a second material layer on the first material layer, wherein the second material layer comprises a second different electrically conductive material.

12. The cover of claim 11 wherein the first molded portion and the second portion each comprise an electrically non-conductive material.

13. The cover of claim 11 wherein the second portion is molded or extruded.

14. The cover of claim 11 wherein the first molded portion comprises a polymer material.

15. The cover of claim 11 wherein the second portion comprises a resilient material.

16. The cover of claim 11 wherein the second portion comprises an elastomer material.

17. The cover of claim 11 wherein the first material layer is a first coating layer deposited on the first molded portion and the second portion.

18. The cover of claim 17 wherein the first coating layer comprises an electrically conductive material.

19. The cover of claim 11 wherein the second material layer is a second coating layer deposited on the first material layer.

20. The cover of claim 19 wherein the second coating layer comprises an environmentally stable electrically conductive metal material.

21. The cover of claim 11 wherein the first material layer is an electrical shield layer, and wherein the second material layer is an environmental protection layer.

22. The cover of claim 11 wherein the first molded portion comprises a polymer material, wherein the second portion comprises an elastomer material, wherein the first material layer comprises a first metallic material, and wherein the second material layer comprises a second metallic material.

23. A method of forming an electrical shield for an electronic device comprising:
molding a first base portion;
molding or extruding a second base portion integrally on the first base portion, wherein the second base portion comprises a resilient material; and
depositing a first coating layer on the first and second base portions, wherein the first coating layer comprises a first electrically conductive material.

24. The method of claim 23 wherein the molding of the second base portion further comprises molding an elastomer base portion integrally with a polymer base portion.

25. The method of claim 24 further comprising depositing a second coating layer on the first coating layer, wherein the first base portion comprises a first electrically non-conductive material, and wherein the second coating layer comprises a second electrically conductive material.
